(19) United States
(12) Patent Application Publication
(10) Pub. No.: US 2007/0298574 A1
(43) Pub. Date: Dec. 27, 2007

(54) METHOD OF FABRICATING DIFFERENT SEMICONDUCTOR DEVICE TYPES WITH REDUCED SETS OF PATTERN LEVELS

(75) Inventors: Shashank S. Ekbote, Allen, TX (US); Frank Scot Johnson, Richardson, TX (US); Srinivasan Chakravarthi, Murphy, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/426,443

(22) Filed: Jun. 26, 2006

(51) Int. Cl. H01L 21/336; H01L 21/76

(52) U.S. Cl. 438/303; 438/449; 257/E29.266; 257/E21.544

(57) ABSTRACT

A method of manufacturing an integrated circuit comprising forming gate structures for first, second and third semiconductor device types located on a semiconductor substrate. A dopant block is formed over the second semiconductor device type and first dopants are implanted into unblocked regions of the semiconductor substrate corresponding to the first and third semiconductor device types. The dopant block is removed and a second dopant block is formed over the first semiconductor device type. Second dopants are implanted into unblocked regions of the semiconductor substrate corresponding to the second and third semiconductor device types.

### TECHNICAL FIELD

The invention is directed, in general, to integrated circuits and their method of manufacture.

### BACKGROUND

Many of today's integrated circuits comprise semiconductor devices, such as metal oxide semiconductor (MOS) transistors, that are designed to perform specific applications. For example, devices can be configured to perform logic operations or memory functions. The construction of such application specific devices, however, necessitates additional manufacturing steps, thereby increasing the cost and time of integrated circuit manufacture. For instance, the implantation of dopants to form three different types of transistors requires three different patterned masking steps and three different implantation steps.

Accordingly, what is needed is a method of manufacturing an integrated circuit having different types of devices that uses less manufacturing steps than prior art methods.

### SUMMARY

The invention provides a method of manufacturing an integrated circuit. The method comprises forming gate structures for first, second and third semiconductor device types located on a semiconductor substrate. A dopant block is formed over the second semiconductor device type. First dopants are implanted into unblocked regions of the semiconductor substrate corresponding to the first and third semiconductor device types. The dopant block is removed and a second dopant block is formed over the first semiconductor device type. Second dopants are implanted into unblocked regions of the semiconductor substrate corresponding to the second and third semiconductor device types.

Another embodiment is an integrated circuit. The integrated circuit comprises first, second and third transistor types in a semiconductor substrate. A region of the substrate corresponding to the third transistor comprises an amount of source and drain extension dopants that is equal to a total amount of source and drain extension dopants implanted into the substrate corresponding to both the first and second transistor types.

### DRAWINGS

FIGS. 1 to 7 illustrate cross-section views of selected steps in an example method of manufacturing an integrated circuit of the invention.

FIG. 8 shows a cross-sectional view of an example integrated circuit of the invention.

### DESCRIPTION

Different semiconductor device types can be fabricated with a reduce set of pattern levels if one of the device types shares the dopants implanted from two or more of different device types. E.g., three different types of semiconductor devices can be manufactured if one of the three devices comprises the sum of the dopants implants of the other two devices. Consequently, two patterned masking steps and two dopant implantation steps are needed to manufacture the three different types of devices. This results in a savings of time and resources compared to previous methods. Although the invention is discussed in the context of forming three different semiconductor device types in an integrated circuit, one skilled in the art would understand how to use the invention to fabricate a plurality of different device types.

In preferred embodiments, the semiconductor devices comprise one or more transistors, and more preferably nMOS and pMOS transistors in a CMOS device. The method, however, could be used to manufacture integrated circuits that contain other types of devices whose construction includes dopant implantation. Such devices could include Junction Field Effect transistors, bipolar transistors, biCMOS transistors, or other conventional semiconductor device components, or combinations thereof.

The term, different devices types, as used herein refers to semiconductor devices are of the same class of devices, but each type has different operating properties that is due at least in part by virtue of the devices receiving differing dopant implantations. E.g., the devices can all be nMOS or pMOS transistors that have different properties as characterized by a different threshold voltage (Vₜ), source-to-drain leakage current (I_{off}), drive current (Iₒₙ), or combinations thereof.

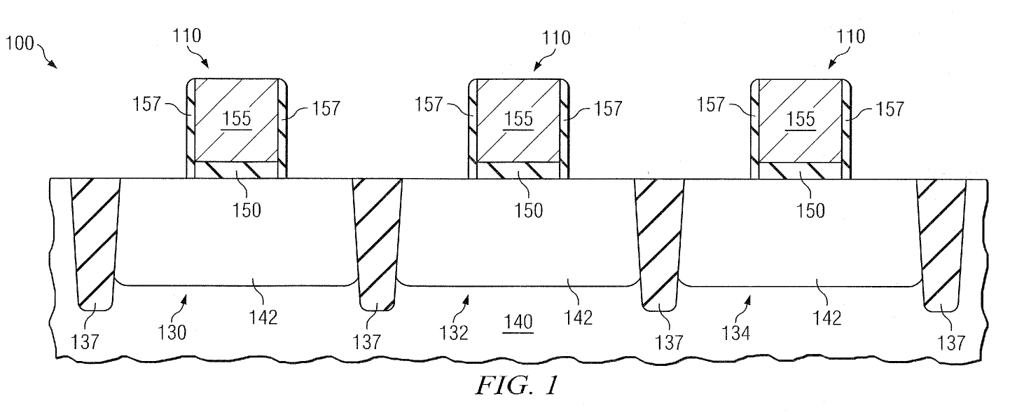

One aspect of the invention is a method of manufacturing an integrated circuit. FIGS. 1-6 show selected steps in example implementations of the method of manufacturing an integrated circuit 100. FIG. 1 shows the circuit 100 after forming gate structures 110 for first, second and third types of semiconductor devices 130, 132, 134 located on a semiconductor substrate 140. For convenience, the different device types 130, 132, 134 are shown located adjacent to each other and separated by isolation structures 137 (e.g., shallow isolation structures or field oxide). In other cases, however, the devices 130, 132, 134 are located in different physical areas of the substrate 140. E.g., some or all of the first device types can be separated from the second and third device types 132, 134, and some or all of the second and third device types 132, 134 separated from each other.

In preferred embodiments, the substrate 140 comprise bulk silicon substrates, semiconductor on insulator substrates, such as a silicon-on-oxide (SOI) substrate, including strained silicon on insulator, such as SiGe on insulator, Ge on insulator, or similarly configured semiconducting materials. The substrate 140 can be doped with suitable n-type or p-type dopants to form doped wells 142. The gate structures 110 can be formed by conventional techniques. E.g., layers of insulating (e.g., silicon dioxide, or higher dielectric constant materials) and conducting material (e.g., polysilicon) can be deposited or grown, and then patterned to form a gate insulator 150 and gate electrode 155, respectively. Oxide, nitride or oxynitride layers can be formed over the gates 110 by e.g., thermal or chemical vapor deposition (CVD) processes, and then patterned to form source and drain extension offset spacers 157. One skilled in the art would be familiar with other conventional materials and processes to form these or other conventional gate structures.

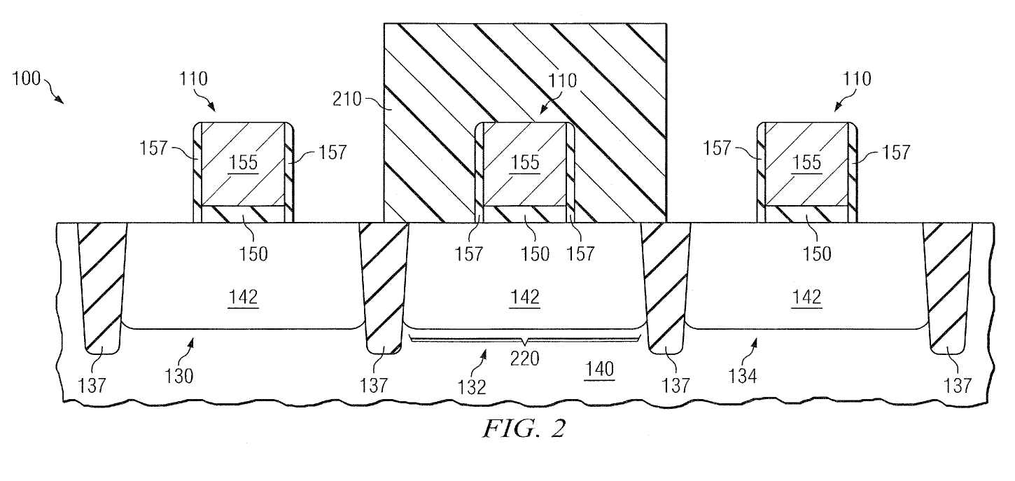

FIG. 2 shows the circuit 100 after forming a dopant block 210 over the second semiconductor device type 132. As illustrated in FIG. 2, the dopant block 210 covers the gate structures 110 of the second semiconductor device 132 and a region 220 of the substrate 140 corresponding to the second semiconductor device 132. In preferred embodiments, the dopant block 210 comprises an ultraviolet or visible photoresist layer that has been patterned such that it masks the second semiconductor device 132 using conventional photolithographic techniques. However, the dopant block 210 can comprise any material that capable of being selectively deposited or patterned, and that will prevent the implantation of dopants into the underlying region of substrate 220.

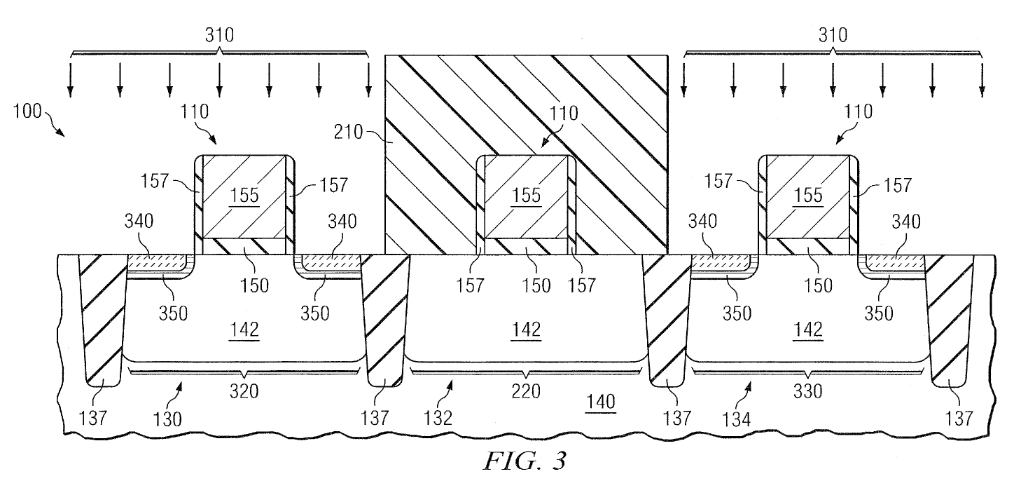

FIG. 3 shows the circuit 100 while implanting first dopants 310 into unblocked regions 320, 330 of the semiconductor substrate 140 that correspond to the first and third semiconductor device types 130, 134, respectively. The type of dopant implanted will depend upon the type of device and the device component being formed. E.g., if the devices 130, 134 are nMOS transistors and a source and drain extension region 340 is being formed, then n-type dopants, such as phosphorus, arsenic or a combination thereof, are implanted. Depending upon the amount dopants implanted, the source and drain extension region 340 may considered to be lightly doped drain (LDD) or middle doped drain (MDD) extensions.

In some preferred embodiments, implanting dopants 310 includes implanting halo dopants (also known as pocket dopants) around a source and drain extension region. One skilled in the art would be familiar with the implantation of halo dopants of the opposite dopant type as the source and drain extension region to, e.g., reduce I_{off}. The halo dopants are implanted in halo regions 350 around the edges of the source and drain extension region 340. E.g., p-type dopants, such as boron, are implanted to form the halo region 350 for devices 130, 132, 134 comprising nMOS transistors, which have an n-type source and drain extension region 340. The opposite dopant types are implanted to construct the source and drain extension regions 340 and halo regions 350 of devices 130, 132, 134 comprising a pMOS transistor.

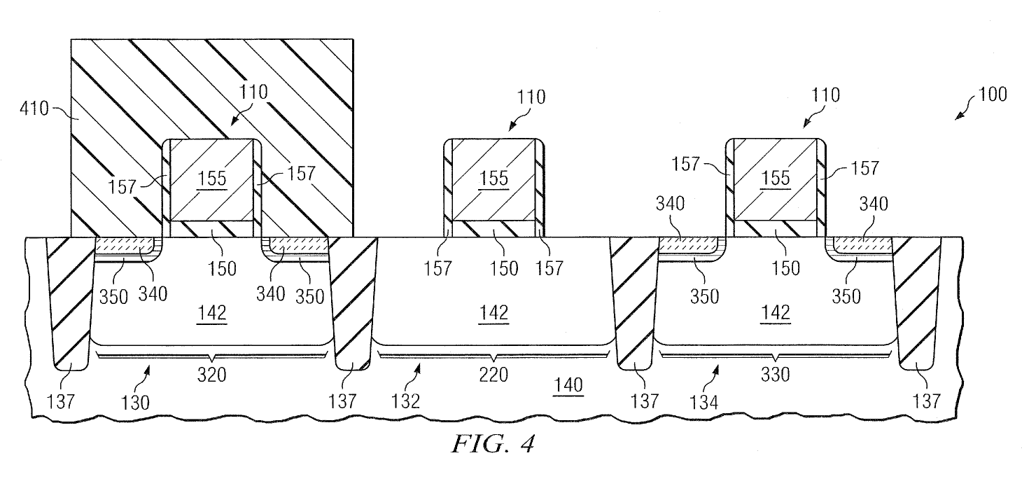

FIG. 4 shows the circuit 100 after removing the dopant block 210 and forming a second dopant block 410 over the first semiconductor device type 130. The dopant block 210 can be removed by conventional techniques. E.g., removal can comprise washing with conventional organic solvents to solubilize and thereby facilitate the removal of a dopant block 210 that comprises a patterned photoresist layer. The second dopant block 410 can be formed using the same or different materials and processes used to form the first dopant block 210.

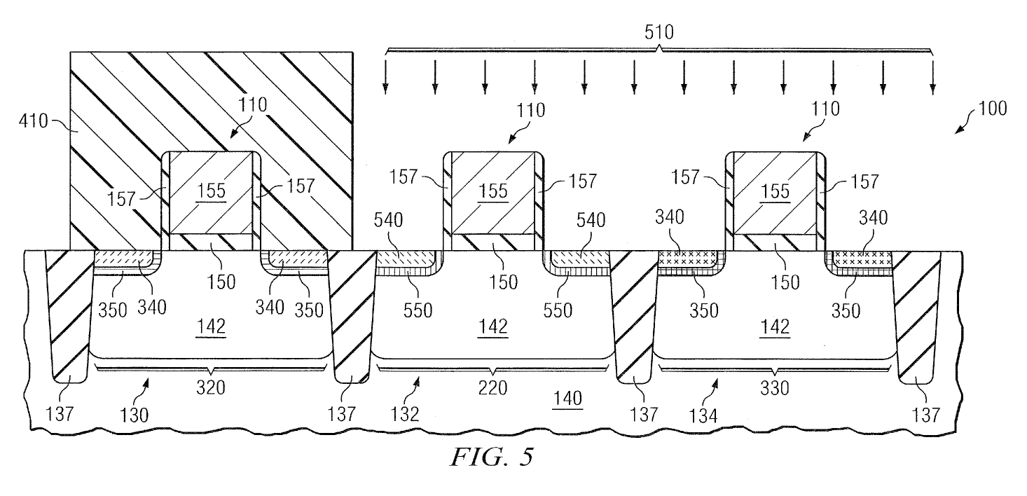

FIG. 5 shows the circuit 100 while implanting second dopants 510 into unblocked regions 220, 330 of the semiconductor substrate 140 corresponding to the second and third semiconductor device types 134, 136, respectively. Similar to that discussed above in the context of FIG. 3, the type of dopant implanted will depend upon the type of transistor and the transistor component being constructed. E.g., the dopants 510 correspond to the appropriate dopants for source and drain extension regions 540 or halo regions 550 of the substrate 140 corresponding to second device types 132.

To construct different types of devices, the regions 320, 220 corresponding to the first and second semiconductor devices 130, 132 preferably receive different dopant implantations for the construction of analogous device components. E.g., the first and second dopants 310, 410 for source and drain extension regions 340, 540 or for halo regions 350, 550 or both, can be of the same dopant type (e.g., both n-type or p-type), but differing amounts of these dopants 310, 410 are implanted into the analogous device regions. Or, the first and second dopants 310, 410 implanted can comprise different elements (e.g., one phosphorous and one arsenic) but the same dopant type (e.g., both n-type). Or, the same amount and type or dopants are implanted into the analogous device region, but the dopants 310, 410 can be implanted using different implantation angles or energies. One skilled in the art would understand the variety of dopant types, concentrations and implantation conditions that could be used to construct analogous device components of the different types of devices 130, 132.

As a result of the implanting and masking steps presented in FIGS. 2-5, the unblocked regions 330 of substrate 140 corresponding to the third semiconductor device type 134 receives both the first dopants 310 and the second dopants 510. E.g., the source and drain extension regions 340 or halo regions 350 of the third device type 134 receive both the first and second dopants 310, 520. Consequently, the dopants implanted into the substrate region 330 of the third semiconductor device type 134 comprise the sum of the first dopants 310 and second dopants 510. This causes the third semiconductor device type 134 to have different operating characteristics than the first and second device types 130, 132.

In some cases, the first semiconductor device 130 type is configured to have a Vₜ that is lower than the Vₜ of the second or third semiconductor device types 132, 134. In some embodiments, the third semiconductor device type 136 is configured to have a Vₜ that is intermediate between the Vₜs of the first and second semiconductor device types 130, 132. E.g., the first semiconductor device type 130 has a Vₜ in a range of about 0.3 to 0.4 Volts, the second semiconductor device type 132 has a Vₜ in a range of about 0.4 to 0.5 Volts, and the third semiconductor device type 134 has a Vₜ in a range of 0.35 to 0.45 Volts.

Adjusting the Vₜs for the different device types is facilitated by choosing different implantation schemes for the devices. E.g., consider the case where the first semiconductor device type 130 has a lower Vₜ than the Vₜs in the second and third semiconductor device types 132, 134. In preferred embodiments, the first dopants 310 implanted into the first device 130 comprise a first dose of source and drain extension dopants that is about 20 to 50 percent greater than a second dose of the second dopants 410 comprising source and drain extension dopants implanted into the second device 134. In some cases, the first dose comprises about 1E+15 n-type atoms per cm², and the second dose comprises 5E+14 n-type atoms per cm². Consequently, the third device type 134 receives a total dose of 1.5E+15, which is the sum of the first and second doses. In some embodiments, a ratio of source and drain extension dopants implanted into the first, second and third semiconductor device types 130, 132, 134 preferably ranges from about 1:0.8:1.8 to 1:0.5:1.5.

In other preferred embodiments, the first dopants 310 implanted into the first device 130 may further or alternatively comprise a first dose of halo dopants that ranges from about 0 to 40 percent greater than a second dose of the second dopants 410 comprising a second dose of halo dopants implanted into the second device 134. In some cases, the first dose comprises about 5E+13 p-type atoms per cm², and the second dose comprises 5E+13 p-type atoms per cm². In this case, the third device type 134 receives a total dose of 1E+14, which is the sum of the first and second doses. In some embodiments, a ratio of halo dopants implanted into the substrate 140 for the first, second and third semiconductor device types ranges from about 1:1:2 to 1:0.6:1.6.

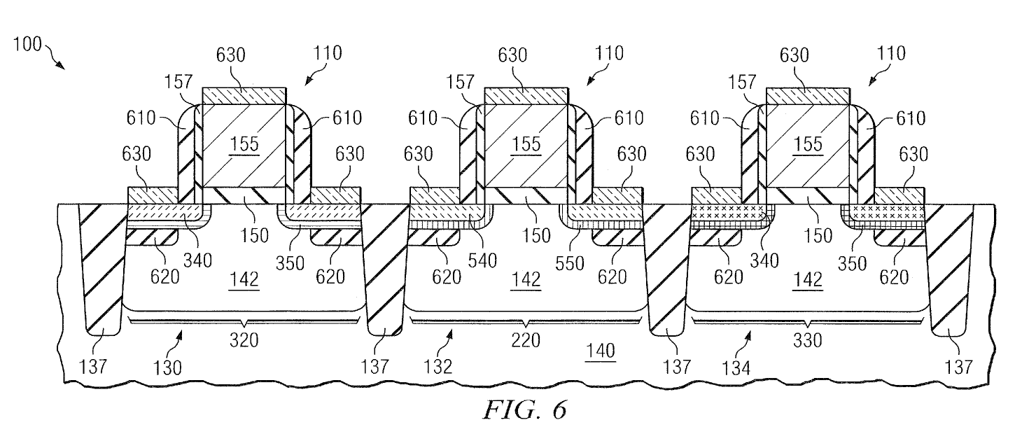

FIG. 6 shows the circuit 100 after forming source and drain sidewalls 610, source and drain regions 620, and metal silicide electrodes 630. Those skilled in the art would be familiar with the conventional techniques that can be used to form such structures. The source and drain sidewalls 610 can be formed using similar techniques to that used to form the source and drain extension offset spacers 157. The metal silicide electrodes 630 can be formed by conventional methods such as, physical vapor depositing a transitional metal (e.g., nickel) over the source and drain regions 620 and then reacting the transitional metal with a silicon-containing substrate 140 by e.g., heating.

FIG. 6 also shows the circuit 100 after performing a thermal anneal to complete the formation of the source and drain extension regions 340, 540 the halo region 350, 550 and the source and drain regions 620. The thermal anneal is performed at a sufficient temperature and duration so as cause dopants 310, 510 (FIGS. 3 and 5) implanted into these regions to diffuse to deeper levels in the substrate 140, to thereby improve the device's performance. E.g., in some cases after the anneal, the source and drain extension regions 340, 540 overlap the perimeter of the gate electrode 155. The thermal anneal also advantageously serves to activate the dopants 310, 410, as well understood by those skilled in the art.

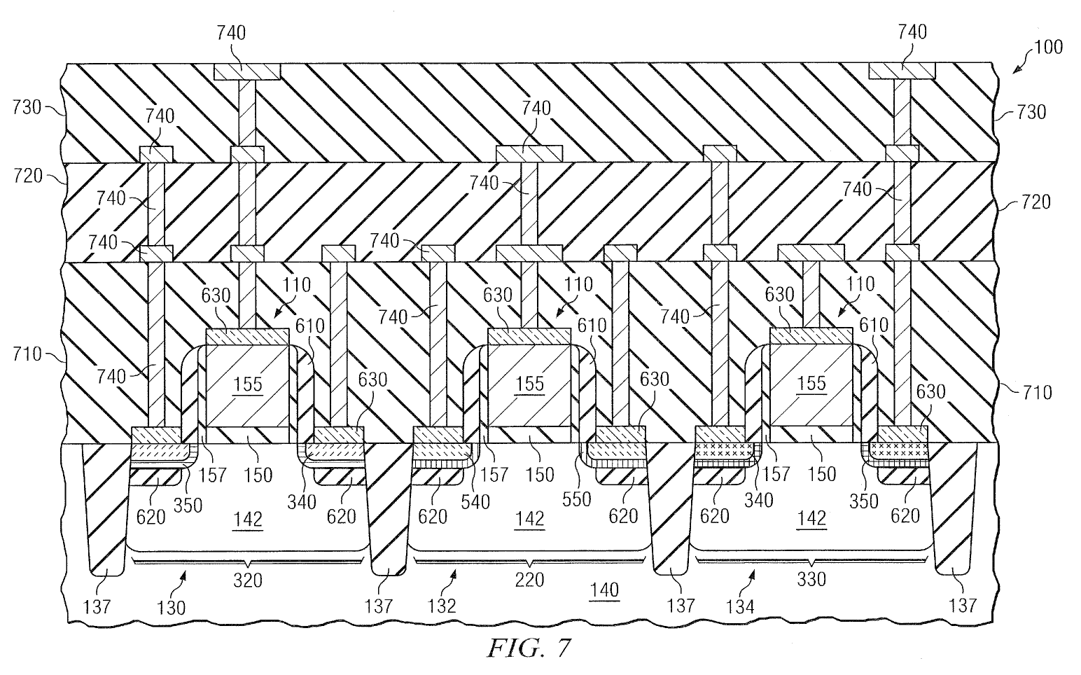

FIG. 7 shows the circuit 100 after forming insulating layers 710, 720, 730 over the first, second and third devices 130, 132, 134. FIG. 7 also shows the circuit after forming interconnects 740 in or on the insulating layers 710, 720, 730, such that one or more of the interconnects 740 contact the devices 130, 132, 134. One skilled in the art would be familiar with the conventional methods and materials that can be used to form the insulating layers 710, 720, 730 and interconnects 740.

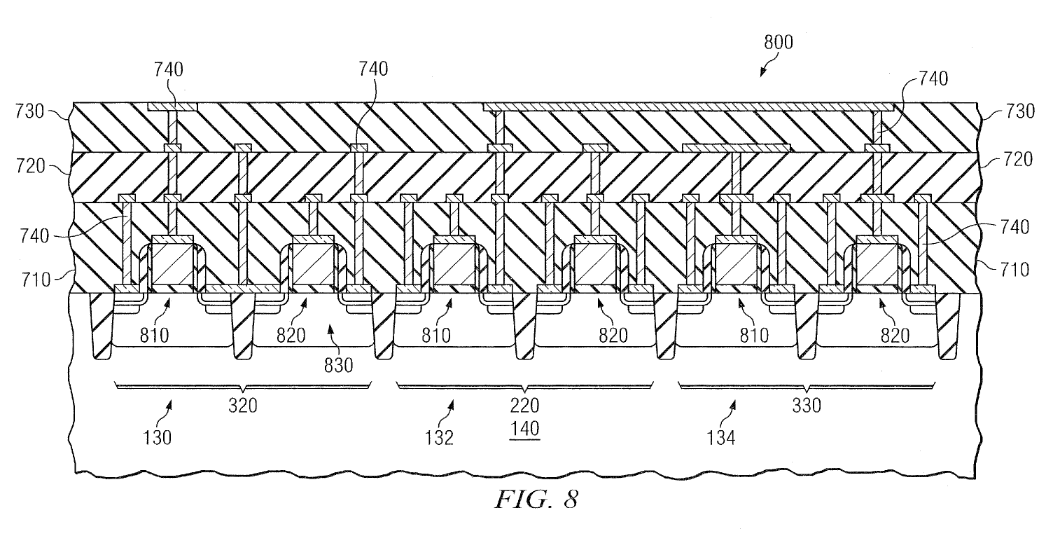

Another aspect of the invention is an integrated circuit. FIG. 8 shows a cross-sectional view of an example integrated circuit 800 of the invention. Any of the processes described in the context of FIGS. 1-7 can used to manufacture the integrated circuit 800, and the circuit 800 can include some of the same features (numbered similarly) as the circuit 100 discussed above.

The circuit 800 comprises semiconductor devices configured as first, second and third transistor types 130, 132, 134 in a semiconductor substrate 140. A region 330 of the substrate 140 corresponding to the third transistor 134 comprises an amount of source and drain extension dopants that is equal to a total amount of source and drain extension dopants 310, 510 (FIGS. 3 and 5) implanted into the substrate 140 the correspond to both the first and second transistor type 130, 132 (e.g., the total source and drain extension dopants implanted in region 320 plus region 220).

In certain preferred embodiments, the dopants implanted 310, 510 (FIGS. 3 and 5) into the first and second transistor types 130, 132 are adjusted to optimize the operating properties of these two transistor types 130, 132 for specific applications. E.g., it may be desirable to have one transistor type 130 that has a low Vₜ, the second transistor type 132 that has a high Vₜ and a third transistor type 134 that has an intermediate Vₜ. In some cases, the difference between the Vₜ of the high Vₜ and low Vₜ transistors is at least about 0.1 Volts.

The transistor type 130 with the low Vₜ is desirable to use in logic applications because such transistors can have a high Iₒₙ (e.g., about 1000 μA/micron or more in some embodiments). E.g., a logic circuit can advantageously comprise transistor types 130 having a low Vₜ and hence high Iₒₙ. Such transistors, however, may have a high I_{off} (e.g., greater than 1 nA/micron in some embodiments) and therefore be inappropriate for applications where information storage is important.

It is advantageous to use the transistor type 132 with the high Vₜ in applications where information storage is important because such transistors can have a low I_{off} (e.g., about 0.1 nA or less in some embodiments). E.g., an SRAM memory cell may advantageously comprise transistor types 132 having a high Vₜ and low I_{off}. Such transistors, however, may have a low Iₒₙ (e.g., less than 500 μA/micron in some embodiments) and therefore may be inappropriate for certain logic application where information-processing speeds are important.

A third transistor type 134 may be used in either logic or memory applications and that have one or more of Vₜ, Iₒₙ or I_{off} that are intermediate in value to that of the first and second transistor types 130, 132. The third transistor type 134 may be advantageously used in applications where having an intermediate performance (e.g., intermediate Iₒₙ) and intermediate current leakage (e.g., intermediate I_{off}) are important. E.g., in some circuits 800, a ratio of Iₒₙ for the first, second and third transistors 130, 132, 134 is about 1:0.6:0.8. In other circuits 800, a ratio of I_{off} for the first, second and third transistors 130, 132, 134 is about 1:0.1:0.5.

In some preferred embodiments, the amount of dopant implanted into the substrate regions of the 320, 220 of the first and second transistor types 130, 132 are preferably adjusted to provide a low and high Vₜ transistor according to the needs of the circuit 800. Consider the example where the circuit design configured to have a first transistor type 130 to comprise one or more higher performance logic transistors, having a low Vₜ and high Iₒₙ. In this example, the second transistor type 132 can be configured to comprise one or more low leakage memory transistors (e.g., SRAM transistors), having a high Vₜ and low I_{off}. The third transistor type 134 can be configured to comprise either logic or memory transistors having an intermediate Vₜ, Iₒₙ or I_{off}. In some such embodiments, a ratio of the source and drain extension dopants implanted into the substrate 140 corresponding to the first, second and third transistor types 130, 132, 134 (e.g., regions 320, 220 and 330, respectively) ranges from 1:0.8:1.8 to 1:0.5:1.5.

In some preferred embodiments, the substrate 330 corresponding to the third transistor 134 comprises an amount of halo dopants that is equal to a total amount of halo dopants implanted into the substrate 140 (e.g., in regions 320, 220, respectively) for both of the first and second transistor types 130, 132. In some embodiments, a ratio of the halo dopants implanted into the substrate 140 corresponding to said first, second and third transistor type ranges from about 1:1:2 to 1:0.6:1.6 to 1:0.6:1.6.

In certain preferred embodiments of the circuit 800, one or more of the first, second and third transistor types comprise 130, 132, 134 one or more nMOS transistor or one or more PMOS transistor. E.g., as shown in FIG. 8, the first transistor types 130, 132, 134 can each comprise nMOS and PMOS transistors, 810, 820. The nMOS and pMOS transistors 810, 820 of each transistor types 130, 132, 134 can be electrically connected, e.g., using interconnects 740 in insulating layers 710, 720, 730 to form an electrical circuit. E.g., as shown for the first transistor type 130, the nMOS and pMOS transistors 810, 820 can be electrically connected to each other, to form a CMOS circuit 830. The nMOS and pMOS transistors 810, 820 of the second and third transistor types 132, 134 could be similarly connected. In other cases, however, the nMOS and pMOS transistors 810, 820 of one transistor type are connected to transistors of the other transistor types. E.g., as shown in FIG. 8, a pMOS transistor 810 of the second transistor type 132 can be electrically connected to an nMOS transistor 820 of the third transistor type 134.

Those skilled in the art to which the invention relates will appreciate that other and further additions, deletions, substitutions and modifications may be made to the described example embodiments, without departing from the invention.

1. A method of manufacturing an integrated circuit comprising:
forming gate structures for first, second and third semiconductor device types located on a semiconductor substrate;
forming a dopant block over said second semiconductor device type;
implanting first dopants into unblocked regions of said semiconductor substrate corresponding to said first and said third semiconductor device types;
removing said dopant block;
forming a second dopant block over said first semiconductor device type; and
implanting second dopants into unblocked regions of said semiconductor substrate corresponding to said second and said third semiconductor device types.

2. The method of claim 1, wherein said unblocked regions of said semiconductor substrate corresponding to said third semiconductor device type receives both said first dopants and said second dopants.

3. The method of claim 1, wherein said first semiconductor device type has a voltage threshold that is greater than voltage thresholds of said second and said third semiconductor device type.

4. The method of claim 1, wherein said third semiconductor device type has a voltage threshold that is between said first and said second semiconductor device type.

5. The method of claim 1, wherein said first semiconductor device type has a voltage threshold in a range of about 0.3 to 0.4 Volts; said second semiconductor device type has a voltage threshold in a range of about 0.4 to 0.5 Volts and said third semiconductor device type has a voltage threshold in a range of 0.35 to 0.45 Volts.

6. The method of claim 1, wherein implanting said first dopants comprises implanting source and drain extension dopants into said semiconductor substrate.

7. The method of claim 1, wherein implanting said first dopants comprises implanting halo dopants into said semiconductor substrate.

8. The method of claim 1, wherein said first dopants comprise a first dose of source and drain extension dopants and said second dopants comprise a second dose of said source and drain extension dopants, wherein said first dose is about 20 to 50 percent greater than said second dose.

9. The method of claim 8, where said first dose comprises about 1E+15 n-type atoms per cm², and said second dose comprises 5E+14 n-type atoms per cm².

10. The method of claim 1, wherein said first dopants comprise a first dose of halo dopants and said second dopants comprise a second dose of said halo dopants, wherein said first dose ranges from about 0 to 40 percent greater than said second dose.

11. The method of claim 10, where said first dose comprises about 5E+15 p-type atoms per cm², and said second dose comprises 5E+14 p-type atoms per cm².

12. The method of claim 1, wherein a ratio of source and drain extension dopants implanted into said first, second and third semiconductor device type ranges from about 1:0.8:1.8 to 1:0.5:1.5.

13. The method of claim 1, wherein a ratio of halo dopants implanted into said substrate for said first, second and third semiconductor device type ranges from about 1:1:2 to 1:0.6:1.6 to 1:0.6:1.6.

14. An integrated circuit, comprising:
first, second and third transistor types in a semiconductor substrate, wherein a region of said substrate corresponding to said third transistor comprises an amount of source and drain extension dopants that is equal to a total amount of source and drain extension dopants implanted into said substrate corresponding to both of said first and said second transistor types.

15. The circuit of claim 14, wherein a ratio of said source and drain extension dopants implanted into said substrate corresponding to said first, second and third transistor type ranges from about 1:0.8:1.8 to 1:0.5:1.5.

16. The circuit of claim 14, wherein said semiconductor substrate of said third transistor type comprises an amount of halo dopants that is equal to a total amount of halo dopants implanted into said substrate corresponding to both of said first and said second transistor types.

17. The circuit of claim 16, wherein a ratio of said halo dopants implanted into said substrate corresponding to said first, second and third transistor type ranges from about 1:1:2 to 1:0.6:1.6 to 1:0.6:1.6.

18. The circuit of claim 14, wherein one or more of said first, second and third transistor types comprise one or more nMOS transistor and one or more pMOS transistor.

19. The circuit of claim 18, wherein said nMOS and said pMOS transistors of each type are electrically connected to each other to form a CMOS circuit.

20. The circuit of claim 14, wherein said first transistor types comprise logic transistors and said second transistor types comprise SRAM transistors.
